(19) United States
(12) Patent Application Publication
(10) Pub. No.: US 2025/0294833 A1
(43) Pub. Date: Sep. 18, 2025

(54) THIN FILM TRANSISTOR AND METHOD OF MANUFACTURING THIN FILM TRANSISTOR

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo XU, Beijing (CN); Chuqiao NIU, Beijing (CN); Gangping YAN, Beijing (CN); Yanyu YANG, Beijing (CN); Yunjiao BAO, Beijing (CN)

(73) Assignees: Beijing Superstring Academy of Memory Technology, Beijing (CN); INSTITUTE OF MICROELECTRONICS, CHINESE ACADEMY OF SCIENCES, Beijing (CN)

(21) Appl. No.: 18/984,959

(22) Filed: Dec. 17, 2024

(30) Foreign Application Priority Data
Mar. 12, 2024 (CN) 202410282420.7

(51) Int. Cl. H10D 62/13; H10D 30/01; H10D 30/62; H10D 30/67

(52) U.S. Cl. CPC H10D 62/151; H10D 30/024; H10D 30/0316; H10D 30/6213; H10D 30/6219; H10D 30/673; H10D 30/6732; H10D 30/6736; H10D 30/6755; H10D 30/6757

(57) ABSTRACT

The present disclosure relates to a thin film transistor and a method of manufacturing a thin film transistor. The thin film transistor includes: a substrate; an insulation layer on an upper surface of the substrate; a fin gate on an upper surface of the insulation layer; a surrounding gate dielectric layer and a surrounding channel, where the surrounding gate dielectric layer covers a top surface of the fin gate and a side surface of the fin gate, and the surrounding channel surrounds an outer wall of the surrounding gate dielectric layer; and a source region and a drain region on the upper surface of the substrate, where the source region and the drain region are located on two opposite sides of the fin gate respectively and are in contact with the surrounding channel.

### CROSS REFERENCE TO RELATED APPLICATION

This application claims priority to Chinese Patent Application No. 202410282420.7, filed on Mar. 12, 2024, the entire content of which is incorporated herein in its entirety by reference.

### TECHNICAL FIELD

The present disclosure relates to a field of transistors, and in particular to a thin film transistor and a method of manufacturing a thin film transistor.

### BACKGROUND

Metal oxide semiconductor thin film transistor (OS-TFT) has a simple structure, with electrical characteristics such as a low leakage current and an excellent mobility. OS-TFT may improve the mobility through component adjustment or doping, and may achieve large-area low-temperature deposition. In addition, OS-TFT is compatible with back-end-of-the-line (BEOL) processes and has a wide range of applications, which is conducive to achieving three-dimensional integration. However, traditional planar OS-TFT devices face a series of performance challenges brought by size miniaturization. Thin film defects and nanoscale effects lead to a low carrier mobility, an increased leakage current, and device performance degradation.

### SUMMARY

In a first aspect of the present disclosure, a thin film transistor is provided, including:
a substrate;
an insulation layer on an upper surface of the substrate;
a fin gate on an upper surface of the insulation layer;
a surrounding gate dielectric layer and a surrounding channel, where the surrounding gate dielectric layer covers a top surface of the fin gate and a side surface of the fin gate, and the surrounding channel surrounds an outer wall of the surrounding gate dielectric layer; and
a source region and a drain region on the upper surface of the substrate, where the source region and the drain region are located on two opposite sides of the fin gate respectively, and the source region and the drain region are in contact with the surrounding channel.

Further, each of the source region and the drain region includes a side portion and a top portion, the top portion of the source region and the top portion of the drain region are located on an upper surface of the surrounding channel, and a spacing between the top portion of the source region and the top portion of the drain region is in a range of 20 nm to 50 nm.

Further, the surrounding channel is made of an IGZO material.

Further, a thickness of the surrounding channel is in a range of 15 nm to 25 nm.

Further, a thickness of the surrounding gate dielectric layer is in a range of 2 nm to 10 nm.

In a second aspect of the present disclosure, a method of manufacturing a thin film transistor is provided, including:
forming an insulation layer on a substrate;
forming a fin gate on the insulation layer;
forming a surrounding gate dielectric layer covering a top surface of the fin gate and a side surface of the fin gate;
forming a surrounding channel on an outer wall of the surrounding gate dielectric layer; and
forming a source region and a drain region on the insulation layer, where the source region and the drain region are located on two opposite sides of the fin gate respectively, and the source region and the drain region are in contact with the surrounding channel.

Further, the method further includes:
forming a conductive layer on an upper surface of the surrounding channel, where the conductive layer is connected to the source region and the drain region; and
etching the conductive layer, so that the source region is spaced from the drain region by a spacing in a range of 20 nm to 50 nm.

Further, the conductive layer is etched using electron beam lithography technology.

Further, the method further includes:
forming a passivation layer, where the passivation layer covers an upper surface of the source region, an upper surface of the drain region and an upper surface of the surrounding channel.

Further, the method further includes:
etching the passivation layer to obtain a contact hole; and
filling the contact hole with a conductive material.

### BRIEF DESCRIPTION OF THE DRAWINGS

Through reading detailed description of preferred embodiments in the following text, various other advantages and benefits will be clearer to those ordinary skilled in the art. The accompanying drawings are only for the purpose of illustrating the preferred embodiments and are not to be considered limiting of the present disclosure.

FIG. 1 is a schematic diagram of a structure of a thin film transistor provided by the present disclosure;

FIG. 2 to FIG. 8 are schematic diagrams of structures obtained in various steps in a method of manufacturing a thin film transistor provided by the present disclosure.

### DETAILED DESCRIPTION OF EMBODIMENTS

Hereinafter, the embodiments of the present disclosure will be described with reference to the accompanying drawings. However, it should be understood that these descriptions are merely exemplary and not intended to limit the scope of the present disclosure. Furthermore, in the following explanation, descriptions of well-known structures and techniques have been omitted to avoid unnecessary confusion of concepts of the present disclosure.

Various structural schematic diagrams according to the embodiments of the present disclosure are shown in the accompanying drawings. These drawings are not drawn to scale, where for the purpose of clarity, some details have been enlarged, and some details have been omitted. Shapes of various regions and layers shown in the drawings and their relative sizes and positional relationships are only exemplary. In practice, there may be deviations due to manufacturing tolerances or technical limitations, and those skilled in the art may design regions/layers with different shapes, sizes, and relative positions as desired in practice.

In the context of the present disclosure, when a layer/element is referred to as being “on” a further layer/element, the layer/element may be directly located on the further layer/element, or there may be a middle layer/element between them. In addition, if a layer/element is located “on” a further layer/element in one orientation, then when the orientation is turned, the layer/element may be located “below” the further layer/element.

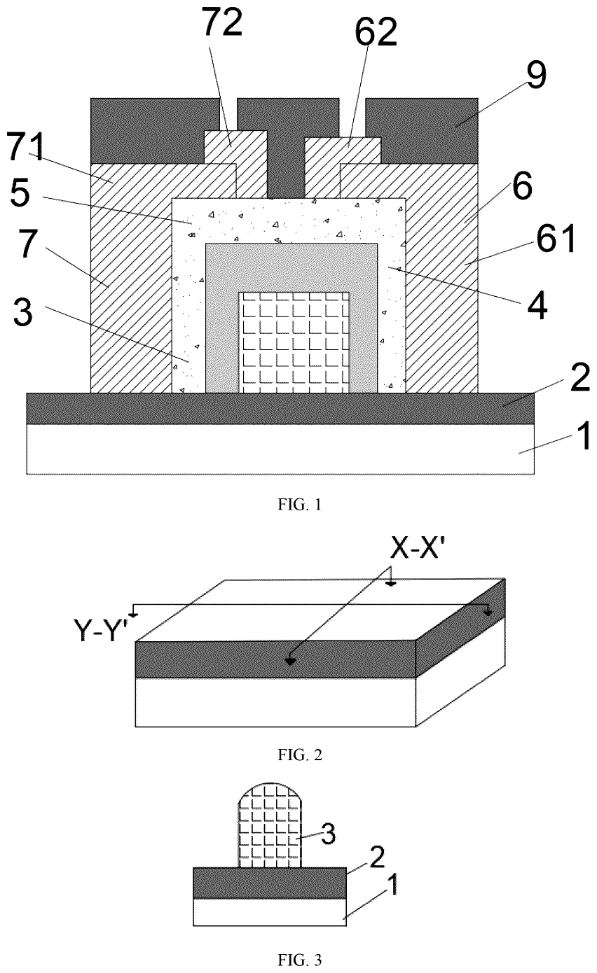

The present disclosure provides a thin film transistor as shown in FIG. 1, which includes: a substrate 1; an insulation layer 2 on an upper surface of the substrate 1; a fin gate 3 on an upper surface of the insulation layer 2; a surrounding gate dielectric layer 4 and a surrounding channel 5, where the surrounding gate dielectric layer 4 covers a top surface of the fin gate and a side surface of the fin gate, and the surrounding channel 5 surrounds an outer wall of the surrounding gate dielectric layer 4; and a source region 6 and a drain region 7 on the upper surface of the substrate 1, where the source region 6 and the drain region 7 are located on two opposite sides of the fin gate 3 respectively, and the source region 6 and the drain region 7 are in contact with the surrounding channel 5.

The above thin film transistor has the following structural characteristics: (1) both the gate and the channel are fin structures (since the channel surrounds the whole surface of the gate, the channel and the gate are conformal to be fin structures); (2) the channel surrounds the gate, and an overlapping area of the channel and the gate is large, so that a control area of the gate on the channel is large.

Based on the above structural characteristics, the thin film transistor may achieve the following effects: the gate control capability of the device is strong, the carrier mobility is high, and it is easy to achieve the three-dimensional integration with high-density and small-size, thereby increasing the on-state current of the device, and achieving a transistor with a high switching ratio.

Therefore, in the present disclosure, a gate in the thin film transistor is designed as a fin structure, which is provided at a bottom of the transistor. In addition, a channel is also a fin structure since the channel surrounds the gate. In this way, the structure has a characteristic of “high aspect ratio”, and an overlapping area of the gate and the channel is large, so as to enhance a gate control capability of the device, improve the carrier mobility, and achieve three-dimensional integration with high-density and small-size, thereby increasing an on-state current of the device and achieving a transistor with a high switching ratio.

In the above thin film transistor, the substrate may be any substrate well-known to those skilled in the art for carrying elements of a semiconductor integrated circuit, such as silicon-on-insulator (SOI), bulk silicon, silicon carbide, germanium, germanium silicon, gallium arsenide, or germanium-on-insulator, etc., and a corresponding top-layer semiconductor material is silicon, germanium, germanium silicon, or gallium arsenide, etc. The substrate may also be a stack structure formed of a plurality of semiconductor material layers. The substrate may also be doped.

The insulation layer 2 may be made of materials such as silicon oxide, silicon oxynitride, nitrogen oxide, etc. In some embodiments, the insulation layer is made of silicon oxide.

The fin gate 3 may be made of metal materials such as tungsten, aluminum, titanium, molybdenum, or a stack of multiple metals. In order to provide better contact between the layers, an arc processing is performed on an outer surface of the fin gate, so that the fin gate may have a curved surface.

An N-type work function metal layer/a P-type work function metal layer may be provided between the fin gate 3 and the surrounding gate dielectric layer.

The surrounding gate dielectric layer 4 may be made of high-k dielectrics such as HfO₂ and Al₂O₃. A thickness of the surrounding gate dielectric layer 4 may be any value in a range of 2 nm to 10 nm.

The surrounding channel 5 may be made of semiconductor materials such as silicon, or oxide semiconductor materials such as IGZO. A thickness of the channel may be any value in a range of 15 nm to 25 nm. In some embodiments, when the channel is made of IGZO, a ratio of In, Ga, Zn, and O may be adjusted by ALD process, and plasma injection process may be performed for doping H to increase the carrier concentration, so as to improve the mobility and suppress a threshold voltage drift, thereby solving the problem of increased power consumption caused by the difficulty in turning off the device, and improving the reliability of the device.

In some embodiments, a patterning process may be performed on the surrounding gate dielectric layer and the surrounding channel, so that the surrounding gate dielectric layer and the surrounding channel may have curved surfaces.

The materials of the source region 6 and the drain region 7 may be semiconductor materials such as silicon, germanium, germanium silicon, or metal materials, which may be doped according to types of transistors or combined with low-temperature activation processes. In some embodiments, each of the source region 6 and the drain region 7 includes a side portion (a side portion 61 of the source region, a side portion 71 of the drain region) and a top portion (a top portion 62 of the source region, a top portion 72 of the drain region) connected to each other. The top portion 62 of the source region and the top portion 72 of the drain region are both located on the upper surface of the surrounding channel 5, and a spacing between the top portion 62 of the source region and the top portion 72 of the drain region is in a range of 20 nm to 50 nm. By using the above structure, the spacing between the source region and the drain region is easy to be controlled. For example, when the spacing is controlled in a range of 20 nm to 50 nm, the spacing between the source region and the drain region is small, which may significantly improve the on-state current and the current switching ratio. In some other embodiments, the source region and the drain region only include the side portions located on two sides of the fin gate, and in this case, the spacing between the source region and the drain region is usually large. In practical applications, the structure of the source region and the drain region may be adjusted according to the required spacing between the source region and the drain region. The “spacing” herein refers to a distance of non-conductive connection between the source region and the drain region. In some embodiments, a passivation layer may be filled between the source region and the drain region.

The present disclosure further provides a method of manufacturing a thin film transistor of FIG. 1, which mainly includes the following steps (described with reference to FIG. 2 to FIG. 8).

Firstly, a substrate 1 is provided, and an insulation layer 2 is formed on the substrate using methods such as PECVD, ALCVD, and oxidation growth method. A three-dimensional structure of the substrate 1 and the insulation layer 2 is shown in FIG. 2.

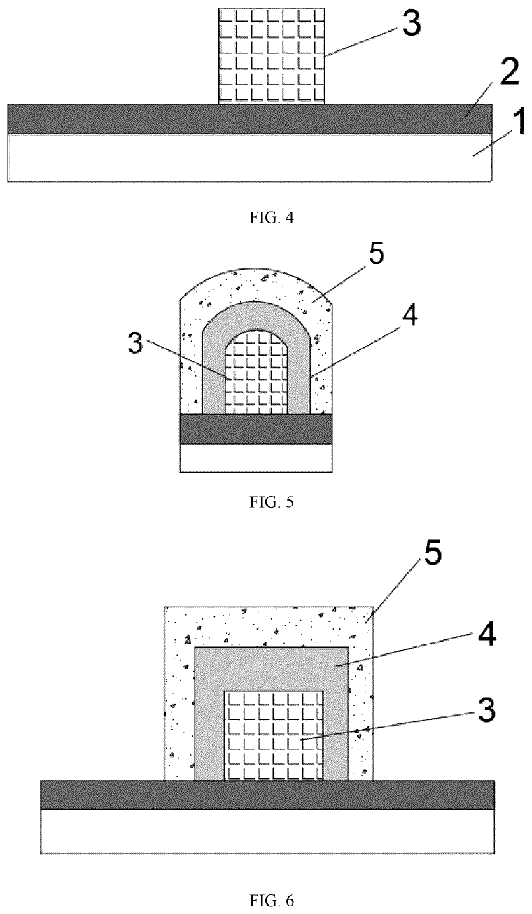

A fin gate 3 is formed on the insulation layer 2. The material may be deposited in a large area using methods such as ALCVD and PECVD, and then a patterning process (including but not limited to CMP, wet etching, etc.) is performed, so as to obtain a desired pattern. A cross-section of the obtained structure in an X-X′ direction is shown in FIG. 3, and a cross-section of the obtained structure in a Y-Y′ direction is shown in FIG. 4.

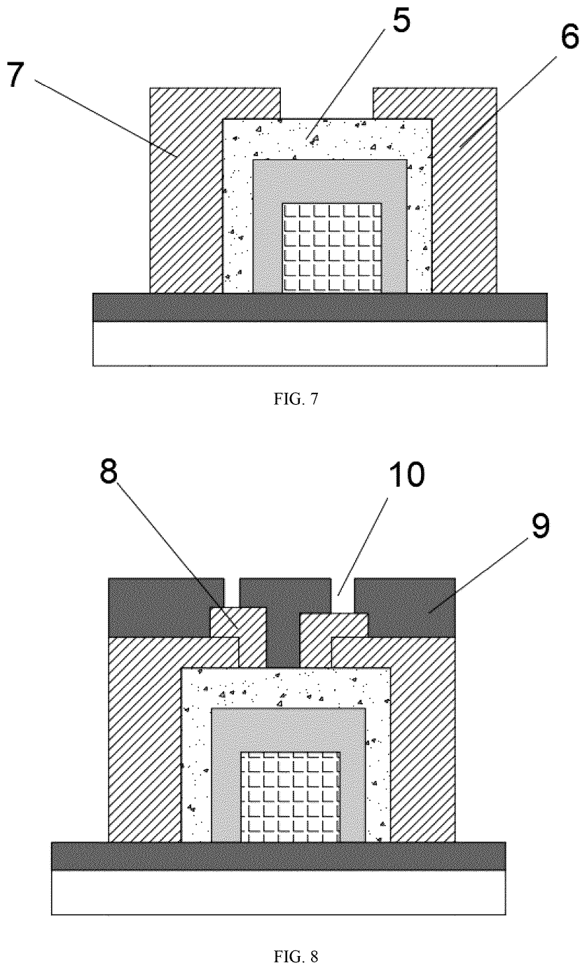

Next, a surrounding gate dielectric layer 4 is formed, which covers a top surface of the fin gate and a side surface of the fin gate. A surrounding channel 5 is then formed on an outer wall of the surrounding gate dielectric layer 4. At this point, the gate, the gate dielectric and the channel are surrounded sequentially from bottom to top, as shown in FIG. 5 (the cross-section in the X-X′ direction) and FIG. 6 (the cross-section in the Y-Y′ direction).

Afterwards, a source region 6 and a drain region 7 are formed on the insulation layer. The source region 6 and the drain region 7 are located on two opposite sides of the fin gate 3 respectively, and the source region 6 and the drain region 7 are in contact with the surrounding channel 5. When forming the source region and the drain region, the material may be usually deposited in a large area and then etched back. The etching back may be performed until only the material on two sides of a stack of the gate, the gate dielectric and the channel are remained, or until a shape shown in FIG. 7 (the cross-section in the Y-Y′ direction) is obtained, where part of the material for the source region and the drain region is remained at the top of the stack. At this time, there is usually a large spacing between the source region 6 and the drain region 7. If it is required to adjust the spacing between the source region 6 and the drain region 7, the next step may be performed.

Next, the same material as the source region 6 and the drain region 7 or other conductive materials may be deposited at the top of the device, so as to form a conductive layer 8. At this point, the conductive layer 8 covers an opening between the source region and the drain region. In order to disconnect the source region and the drain region, it is required to etch back the conductive layer (using electron beam lithography technology). A hard mask such as silicon oxide may be used to etch back, so as to form a narrow channel, such as a channel by which the source region 6 is spaced from the drain region 7 by a spacing in a range of 20 nm to 50 nm, as shown in FIG. 8 (the cross-section in the Y-Y′ direction).

If there is no requirement for adjusting the spacing between the source region and the drain region, the previous step does not require to be performed.

A passivation layer 9 is formed. A back-end-of-the-line process is performed, including etching the passivation layer 9 to obtain a contact hole 10, and filling the contact hole 10 with a conductive material (not shown in the figure) to form a contact plug, thereby leading out the source region and the drain region to a power supply, as shown in FIG. 8.

Compared with the related art, the present disclosure has achieved the following technical effects: the design of a novel back gate Fin-type OS-TFT structure with a high aspect ratio may significantly enhance the gate control capability of the device, improve the channel carrier mobility and a switching speed, increase a control area of the gate on the channel, and reduce the leakage current. At the same time, a channel length of the device is reduced to a nanoscale, which may significantly improve the working current and the current switching ratio of the device. In addition, the manufacturing process of the device is simple and compatible with CMOS process.

The embodiments of the present disclosure are described above. However, these embodiments are only for illustrative purposes and not to limit the scope of the present disclosure. The scope of the present disclosure is defined by the appended claims and their equivalents. Without departing from the scope of the present disclosure, those skilled in the art may make various substitutions and modifications, all of which should fall within the scope of the present disclosure.

What is claimed is:

1. A thin film transistor, comprising:
a substrate;
an insulation layer on an upper surface of the substrate;
a fin gate on an upper surface of the insulation layer;
a surrounding gate dielectric layer and a surrounding channel, wherein the surrounding gate dielectric layer covers a top surface of the fin gate and a side surface of the fin gate, and the surrounding channel surrounds an outer wall of the surrounding gate dielectric layer; and
a source region and a drain region on the upper surface of the substrate, wherein the source region and the drain region are located on two opposite sides of the fin gate respectively, and the source region and the drain region are in contact with the surrounding channel.

2. The thin film transistor according to claim 1, wherein each of the source region and the drain region comprises a side portion and a top portion, the top portion of the source region and the top portion of the drain region are located on an upper surface of the surrounding channel, and a spacing between the top portion of the source region and the top portion of the drain region is in a range of 20 nm to 50 nm.

3. The thin film transistor according to claim 1, wherein the surrounding channel is made of an IGZO material.

4. The thin film transistor according to claim 1, wherein a thickness of the surrounding channel is in a range of 15 nm to 25 nm.

5. The thin film transistor according to claim 1, wherein a thickness of the surrounding gate dielectric layer is in a range of 2 nm to 10 nm.

6. The thin film transistor according to claim 4, wherein a thickness of the surrounding gate dielectric layer is in a range of 2 nm to 10 nm.

7. A method of manufacturing a thin film transistor, comprising:
forming an insulation layer on a substrate;
forming a fin gate on the insulation layer;
forming a surrounding gate dielectric layer covering a top surface of the fin gate and a side surface of the fin gate;
forming a surrounding channel on an outer wall of the surrounding gate dielectric layer; and
forming a source region and a drain region on the insulation layer, wherein the source region and the drain region are located on two opposite sides of the fin gate respectively, and the source region and the drain region are in contact with the surrounding channel.

8. The method according to claim 7, further comprising:
forming a conductive layer on an upper surface of the surrounding channel, wherein the conductive layer is connected to the source region and the drain region; and
etching the conductive layer, so that the source region is spaced from the drain region by a spacing in a range of 20 nm to 50 nm.

9. The method according to claim 8, wherein the conductive layer is etched using electron beam lithography technology.

10. The method according to claim 7, further comprising:
forming a passivation layer, wherein the passivation layer covers an upper surface of the source region, an upper surface of the drain region and an upper surface of the surrounding channel.

11. The method according to claim 10, further comprising:
etching the passivation layer to obtain a contact hole; and
filling the contact hole with a conductive material.
